(19) United States
(12) Patent Application Publication
(10) Pub. No.: US 2026/0163528 A1
(43) Pub. Date: Jun. 11, 2026

(54) POWER AMPLIFIER CIRCUIT

(71) Applicant: Murata Manufacturing Co., Ltd., Kyoto (JP)

(72) Inventor: Hisanori NAMIE, Kyoto (JP)

(21) Appl. No.: 19/179,476

(22) Filed: Apr. 15, 2025

(30) Foreign Application Priority Data
Apr. 19, 2024 (JP) 2024-068309

(51) Int. Cl. H03F 1/02; H03F 1/56; H03F 3/21

(52) U.S. Cl. CPC H03F 1/0288; H03F 1/56; H03F 3/211; H03F 2200/222; H03F 2200/387; H03F 2200/451

(57) ABSTRACT

A power amplifier circuit is provided which has a configuration including a distributor circuit adding a phase difference to an input signal for distribution, amplifier circuits amplifying the distributed signals, and a combining circuit combining the signals with reduction of the phase difference, and that enables the distortion characteristics and efficiency to be improved.

### CROSS REFERENCE TO RELATED APPLICATION

This application claims priority from Japanese Patent Application No. 2024-068309, filed on Apr. 19, 2024. The content of the application is incorporated herein by reference in its entirety.

### BACKGROUND OF THE DISCLOSURE

### 1. Field of the Disclosure

The present disclosure relates to a power amplifier circuit.

### 2. Description of the Related Art

A power amplifier includes an emitter-grounded bipolar transistor having a base terminal and a collector terminal, a resistive element connected between a base-bias voltage supply terminal and the base terminal, a first capacitor connected between a signal input terminal and the base terminal, and a second capacitor connected between the signal input terminal and the base-bias voltage supply terminal (for example, see Japanese Unexamined Patent Application Publication No. 2003-324325).

### BRIEF SUMMARY OF THE DISCLOSURE

In the power amplifier described in Japanese Unexamined Patent Application Publication No. 2003-324325, a bypass path for high frequency components through the first capacitor and the second capacitor is formed across the resistive element connected between the base terminal of the bipolar transistor and the base-bias voltage supply terminal, enabling an operation with low distortion.

There is a demand that a power amplifier circuit, which has a configuration including a distributor circuit adding a phase difference to an input signal for distribution, amplifier circuits amplifying the distributed signals, and a combining circuit combining the signals with reduction of the phase difference, have excellent distortion characteristics and efficiency.

The present disclosure is made in view of such a situation, and a possible benefit thereof is to provide a power amplifier circuit that has a configuration including a distributor circuit adding a phase difference to an input signal for distribution, amplifier circuits amplifying the distributed signals, and a combining circuit combining the signals with reduction of the phase difference, and that enables the distortion characteristics and efficiency to be improved.

A power amplifier circuit according to an aspect of the present disclosure includes a distributor circuit that distributes a first signal into a second signal and a third signal having a phase delayed from the phase of the second signal, and that has a first output terminal and a second output terminal which output the second signal and the third signal, respectively; a carrier amplifier that has a first input terminal connected to the first output terminal through a first capacitor, the first input terminal being supplied with the second signal, and that amplifies the second signal to output a first amplified signal; a peak amplifier that has a second input terminal connected to the second output terminal through a second capacitor, the second input terminal being supplied with the third signal, and that amplifies the third signal to output a second amplified signal; a combining circuit that combines the first amplified signal with the second amplified signal to generate a third amplified signal; a first biasing circuit that has a first bias supply terminal which supplies a first bias to the first input terminal through a first resistive element; a second biasing circuit that has a second bias supply terminal which supplies a second bias to the second input terminal through a second resistive element; and a third capacitor that has a first end connected to the second output terminal and a second end connected to the first bias supply terminal.

The present disclosure may provide a power amplifier circuit that has a configuration including a distributor circuit adding a phase difference to an input signal for distribution, amplifier circuits amplifying the distributed signals, and a combining circuit combining the signals with reduction of the phase difference, and that enables the distortion characteristics and efficiency to be improved.

### BRIEF DESCRIPTION OF THE SEVERAL VIEWS OF THE DRAWINGS

FIG. 1 is a circuit diagram of a power amplifier circuit 101;

FIG. 2 is a circuit diagram of a power amplifier circuit 901 which is a reference example;

FIG. 3 is diagram illustrating temporal changes with respect to amplified signals and bias voltages of the power amplifier circuits 101 and 901;

FIG. 4 is a diagram illustrating an example of power added efficiency (PAE) characteristics of the power amplifier circuits 101 and 901;

FIG. 5 is a diagram illustrating an example of amplitude to phase modulation (AM/PM) characteristics of the power amplifier circuits 101 and 901;

FIG. 6 is a diagram illustrating an example of gain characteristics of the power amplifier circuits 101 and 901;

FIG. 7 is a diagram illustrating an example of amplitude to amplitude modulation (AM/AM) characteristics of the power amplifier circuits 101 and 901; and

FIG. 8 is a circuit diagram of a power amplifier circuit 102.

### DETAILED DESCRIPTION OF THE DISCLOSURE

Embodiments of the present disclosure will be described in detail below by referring to the drawings. The same components are designated with the same reference numerals, and repeated description will be avoided as much as possible.

### First Embodiment

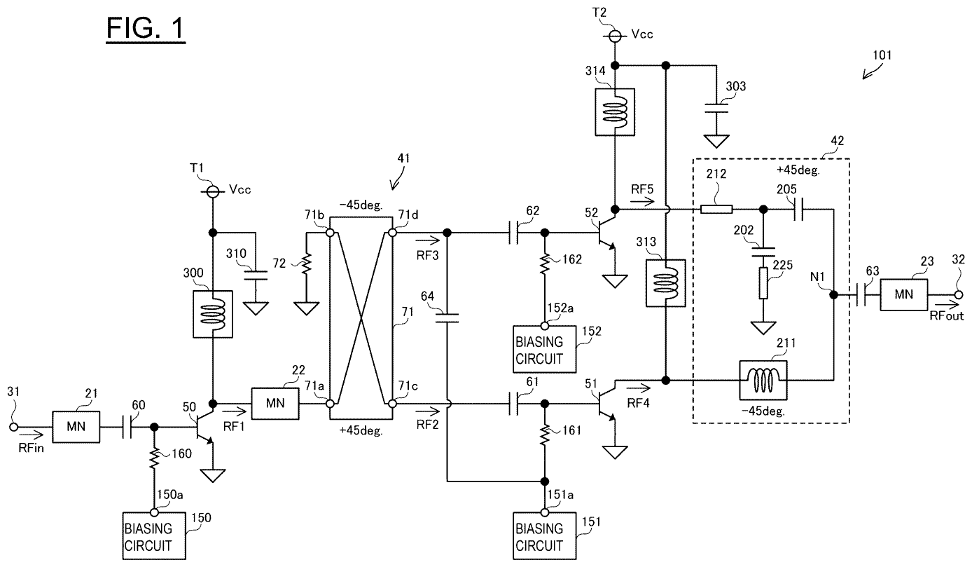

A power amplifier circuit 101 according to a first embodiment will be described. FIG. 1 is a circuit diagram of the power amplifier circuit 101. As illustrated in FIG. 1, the power amplifier circuit 101 includes capacitors 60, 61 (first capacitor), 62 (second capacitor), 63, 64 (third capacitor), 303, and 310, matching circuits 21, 22, and 23, a distributor circuit 41, a combining circuit 42, transistor devices 50, 51, and 52, biasing circuits 150, 151 (first biasing circuit), and 152 (second biasing circuit), resistive elements 160, 161 (first resistive element), and 162 (second resistive element), and inductors 300, 313, and 314.

In the present embodiment, each transistor device is configured, for example, by a bipolar transistor such as a heterojunction bipolar transistor (HBT). Each transistor device may be configured by another transistor such as a metal-oxide-semiconductor field-effect transistor (MOSFET). In this case, the terms, “base”, “collector”, and “emitter”, may be replaced with “gate”, “drain”, and “source”, respectively.

The matching circuit 21 in the power amplifier circuit 101, which is disposed between an input terminal 31 and the capacitor 60, matches the impedance between a circuit (not illustrated), which is disposed immediately prior to the input terminal 31, and the capacitor 60.

The capacitor 60, which is disposed, for example, for cutting direct current (DC), has a first end connected to the input terminal 31 through the matching circuit 21, and a second end.

The transistor device 50 is a driver stage amplifier. Specifically, the transistor device 50 has the base, which is connected to the second end of the capacitor 60, the emitter, which is grounded, and the collector. The transistor device 50 amplifies an input signal RFin, which is supplied from the input terminal 31 through the matching circuit 21 and the capacitor 60 to the base, and outputs an amplified signal RF1 from the collector.

The biasing circuit 150 generates a bias, which is to be supplied to the base of the transistor device 50, for the output from a bias supply terminal 150a. The bias supply terminal 150a is connected to the base of the transistor device 50 through the resistive element 160.

A voltage supply terminal T1, which supplies a power supply voltage Vcc for operating the transistor device 50, is connected to the collector of the transistor device 50 through the inductor 300. The capacitor 310, which is disposed between the voltage supply terminal T1 and the ground, functions as a filter for attenuating harmonic waves.

The matching circuit 22, which is disposed between the transistor device 50 and the distributor circuit 41, matches the impedance between the transistor device 50 and the distributor circuit 41.

The distributor circuit 41 distributes the amplified signal RF1 (first signal), which is supplied from the collector of the transistor device 50 through the matching circuit 22, into an amplified signal RF2 (second signal) and an amplified signal RF3 (third signal) which has a phase delayed by approximately 90° from the phase of the amplified signal RF2.

In the present embodiment, the distributor circuit 41 includes a 90° coupler 71 and a resistive element 72. The 90° coupler 71 has ports 71a, 71b, 71c (first output terminal), and 71d (second output terminal).

The port 71a, which is an input port, is connected to the collector of the transistor device 50 through the matching circuit 22. The port 71b, which is an isolation port, is grounded through the resistive element 72. The ports 71c and 71d, which are output ports, output the amplified signals RF2 and RF3, respectively.

The capacitor 61, which is disposed for cutting DC, has a first end connected to the port 71c of the 90° coupler 71, and a second end.

The transistor device 51 is a carrier amplifier. Specifically, the transistor device 51 has the base (first input terminal) which is connected to the second end of the capacitor 61, the emitter which is grounded, and the collector. The transistor device 51 amplifies the amplified signal RF2 supplied from the port 71c of the 90° coupler 71 through the capacitor 61 to the base, and outputs an amplified signal RF4 (first amplified signal) from the collector.

The biasing circuit 151 generates a first bias that is to be supplied to the base of the transistor device 51 through the resistive element 161, for the output from a bias supply terminal 151a (first bias supply terminal). The bias supply terminal 151a is connected to the base of the transistor device 51 through the resistive element 161. In the present embodiment, the transistor device 51 performs Class A operation or Class AB operation in accordance with the first bias supplied from the biasing circuit 151.

The capacitor 62, which is disposed for cutting DC, has a first end connected to the port 71d of the 90° coupler 71, and a second end.

The transistor device 52 is a peak amplifier. Specifically, the transistor device 52 has the base (second input terminal) which is connected to the second end of the capacitor 62, the emitter which is grounded, and the collector. The transistor device 52 amplifies the amplified signal RF3 supplied from the port 71d of the 90° coupler 71 through the capacitor 62 to the base, and outputs an amplified signal RF5 (second amplified signal) from the collector.

The biasing circuit 152 generates a low bias (second bias) or a high bias (second bias) that is to be supplied to the base of the transistor device 52 through the resistive element 162, for the output from a bias supply terminal 152a (second bias supply terminal). The bias supply terminal 152a is connected to the base of the transistor device 52 through the resistive element 162.

In the present embodiment, for example, the biasing circuit 152 switches the bias point (operating point or operating class) of the transistor device 52 between a low bias point and a high bias point higher than the low bias point. For example, the biasing circuit 152 supplies the transistor device 52 with either one of the low bias and the high bias higher than the low bias.

When the high bias is supplied to the transistor device 52, the power amplifier circuit 101 enters the balance mode. At that time, the bias point of the transistor device 52 is set to the high bias point, and the transistor device 52 performs, for example, Class A operation or Class AB operation. Thus, the power amplifier circuit 101 operates as a balanced amplifier.

In contrast, when the low bias is supplied to the transistor device 52, the power amplifier circuit 101 enters the Doherty mode. At that time, the bias point of the transistor device 52 is set to the low bias point, and the transistor device 52 performs, for example, Class AB operation or Class B operation. Thus, the power amplifier circuit 101 operates as a Doherty amplifier.

A voltage supply terminal T2, which supplies the power supply voltage Vcc for operating the transistor devices 51 and 52, is connected to the respective collectors of the transistor devices 51 and 52 through the inductors 313 and 314. The capacitor 303, which is disposed between the voltage supply terminal T2 and the ground, functions as a filter for attenuating harmonic waves.

The capacitor 64 has a first end connected to the port 71d of the 90° coupler 71, and a second end connected to the bias supply terminal 151a of the biasing circuit 151.

The combining circuit 42 reduces the phase difference between the amplified signals RF4 and RF5 which are supplied from the transistor devices 51 and 52, respectively, and combines the amplified signals RF4 and RF5 to generate an output signal RFout (third amplified signal). The combining circuit 42 outputs the output signal RFout to an output terminal 32 through the capacitor 63 and the matching circuit 23.

In the present embodiment, the combining circuit 42 includes capacitors 202 and 205 and inductors 211, 212, and 225.

The inductor 212 has a first end connected to the collector of the transistor device 52, and a second end. The inductor 225 has a first end which is connected to the second end of the inductor 212 through the capacitor 202, and a second end which is grounded. The capacitor 205 has a first end which is connected to the second end of the inductor 212, and a second end which is connected to a node N1. The inductor 211 has a first end which is connected to the collector of the transistor device 51, and a second end which is connected to the node N1.

The capacitor 63, which is disposed for cutting DC, has a first end connected to the node N1, and a second end.

The matching circuit 23, which is disposed between the capacitor 63 and the output terminal 32, matches the impedance between the capacitor 63 and a circuit (not illustrated) which is disposed immediately subsequent to the output terminal 32.

### Reference Example

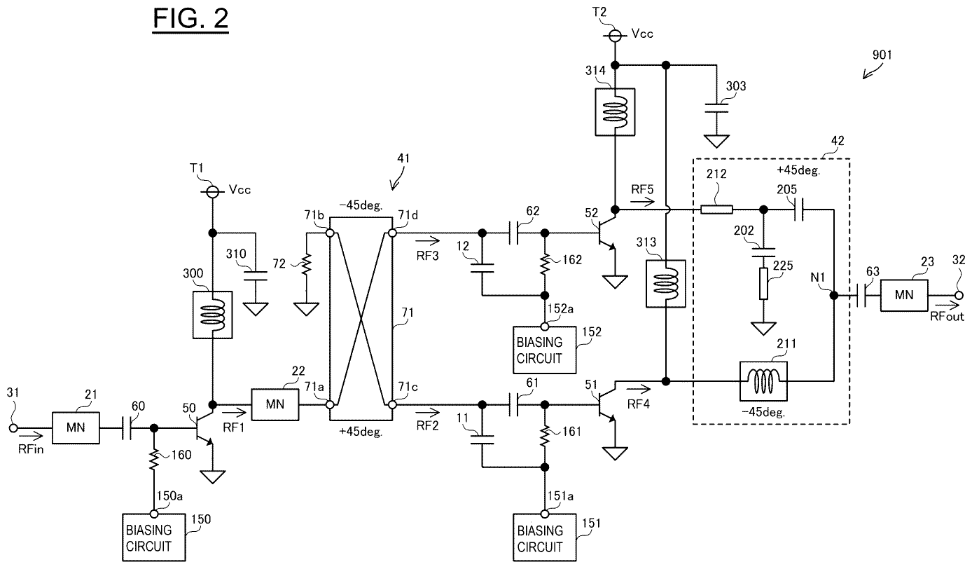

A power amplifier circuit 901, which is a reference example, will be described. FIG. 2 is a circuit diagram of the power amplifier circuit 901 which is a reference example. Compared with the power amplifier circuit 101, the power amplifier circuit 901 includes capacitors 11 and 12 instead of the capacitor 64.

The capacitor 11 has a first end connected to the port 71c of the 90° coupler 71, and a second end connected to the bias supply terminal 151a of the biasing circuit 151.

The capacitor 12 has a first end connected to the port 71d of the 90° coupler 71, and a second end connected to the bias supply terminal 152a of the biasing circuit 152.

### Effects

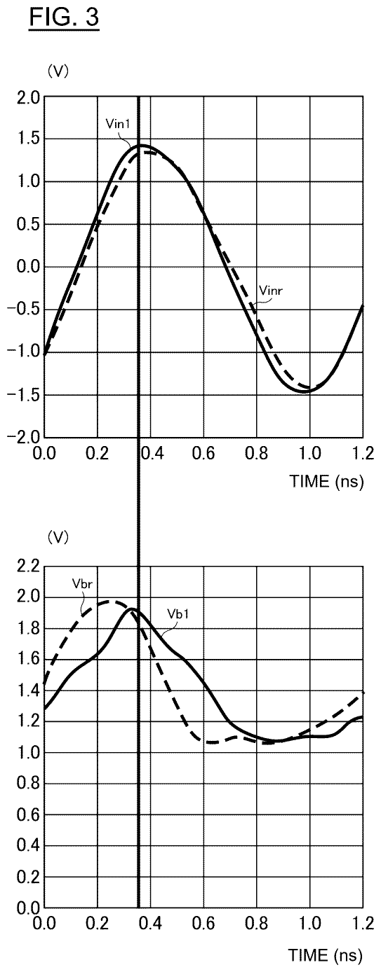

FIG. 3 is a diagram illustrating an example of temporal changes of amplified signals and bias voltages of the power amplifier circuits 101 and 901. The vertical axis indicates voltage having a unit of “V”. The horizontal axis indicates time having a unit of “ns”. Curves Vin1 and Vinr indicate temporal changes of the voltage at the port 71c in the power amplifier circuits 101 and 901, respectively. Curves Vb1 and Vbr indicate temporal changes of the voltage at the bias supply terminal 151a in the power amplifier circuits 101 and 901, respectively.

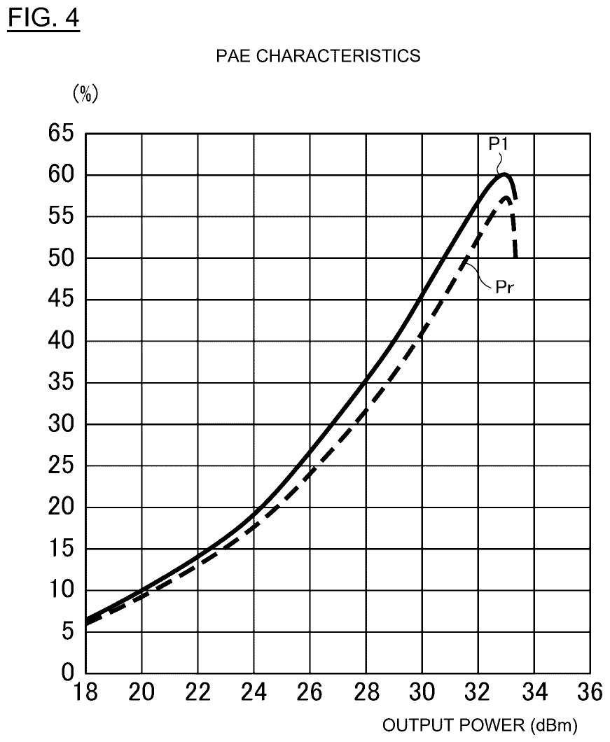

FIG. 4 is a diagram illustrating an example of PAE characteristics of the power amplifier circuits 101 and 901. The vertical axis indicates PAE having a unit of “%”. The horizontal axis indicates output power having a unit of “dBm”. Curves P1 and Pr indicate changes of PAE with respect to the output power in the power amplifier circuits 101 and 901, respectively.

As illustrated in FIGS. 3 and 4, in the power amplifier circuit 901, the phase of the voltage at the bias supply terminal 151a delays from the phase of the amplified signal RF2 at the port 71c. Therefore, the PAE of the power amplifier circuit 901 degrades compared with that of the power amplifier circuit 101.

In contrast, the power amplifier circuit 101 may make the phase of the voltage at the bias supply terminal 151a close to the phase of the amplified signal RF2 at the port 71c. Thus, the PAE of the power amplifier circuit 101 may be improved compared with that of the power amplifier circuit 901.

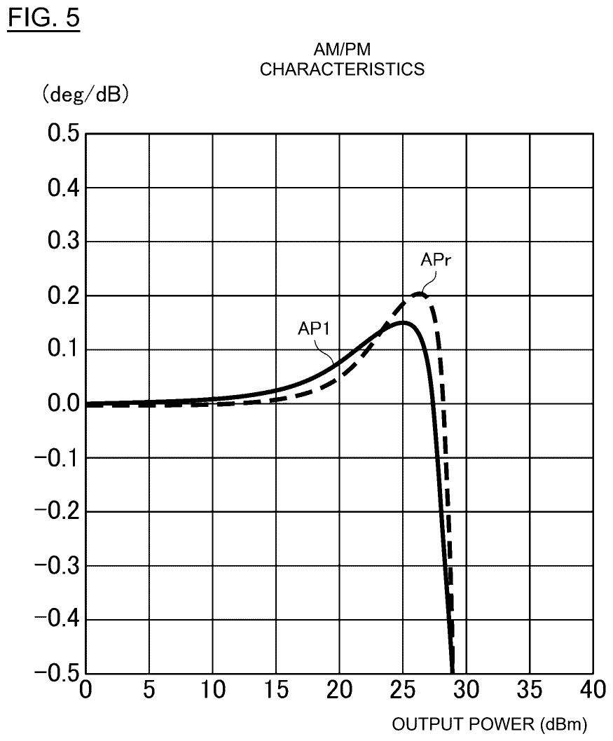

FIG. 5 is a diagram illustrating an example of amplitude to phase modulation (AM/PM) characteristics of the power amplifier circuits 101 and 901. The vertical axis indicates gradient of voltage phase having a unit of “deg/dB”. The horizontal axis indicates output power having a unit of “dBm”. Curves AP1 and APr indicate changes of gradient of phase with respect to the output power in the power amplifier circuits 101 and 901, respectively.

As illustrated in FIG. 5, in the power amplifier circuit 901, the capacitors 11 and 12 intensify the base bias amplitude, achieving suppression of degradation of the AM/PM characteristics. The power amplifier circuit 101 may achieve AM/PM characteristics equivalent to or better than those of the power amplifier circuit 901.

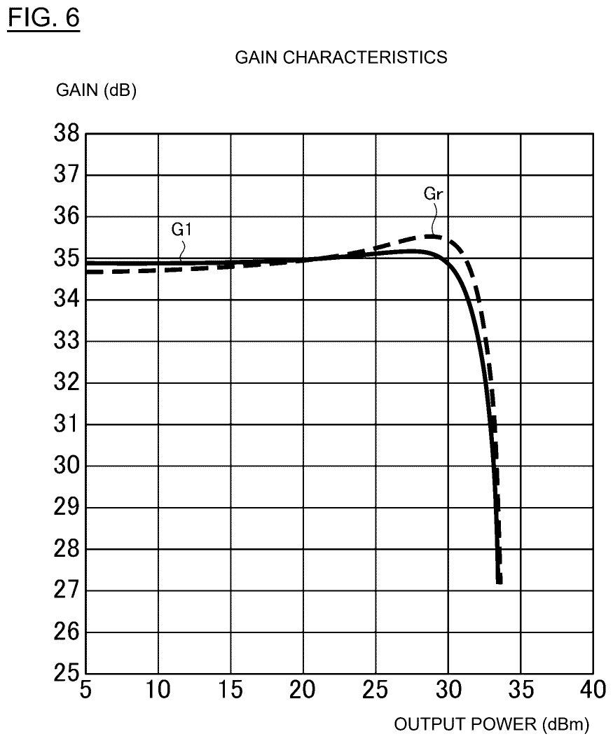

FIG. 6 is a diagram illustrating an example of gain characteristics of the power amplifier circuits 101 and 901. The vertical axis indicates gain having a unit of “dB”. The horizontal axis indicates output power having a unit of “dBm”. Curves G1 and Gr indicate changes of gain with respect to the output power in the power amplifier circuits 101 and 901, respectively.

As illustrated in FIG. 6, compared with the power amplifier circuit 901, the power amplifier circuit 101 achieves suppression of change of gain with respect to the output power.

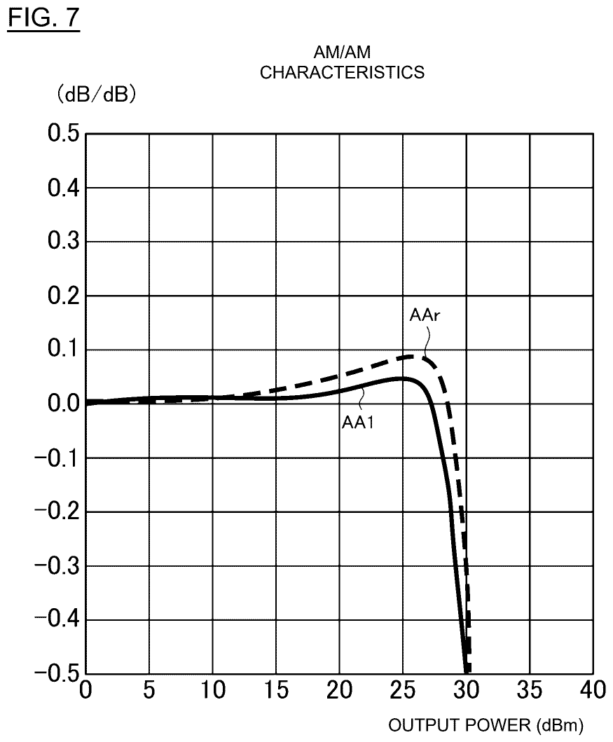

FIG. 7 is a diagram illustrating an example of amplitude to amplitude modulation (AM/AM) characteristics of the power amplifier circuits 101 and 901. The vertical axis indicates dimensionless quantity indicating gradient of gain of voltage having a unit of “dB/dB”. The horizontal axis indicates output power having a unit of “dBm”. Curves AA1 and AAr indicate changes of gradient of gain with respect to the output power in the power amplifier circuits 101 and 901, respectively.

As illustrated in FIG. 7, the power amplifier circuit 101 achieves AM/AM characteristics equivalent to or better than those of the power amplifier circuit 901. Thus, the distortion characteristics may be improved.

In the present embodiment, the configuration in which the amplified signal RF3 has a phase which delays by approximately 90° from the phase of the amplified signal RF2 is described. However, the configuration is not limited to this. Any configuration may be employed as long as the amplified signal RF3 has a phase which delays from the phase of the amplified signal RF2. Specifically, the amplified signal RF3 may be any as long as its phase delays by an angle greater than 0° and less than 180° from the phase of the amplified signal RF2 which is used as a reference. In the present specification, the term “approximately 90°” means greater than or equal to 70° and less than or equal to 110°.

### Second Embodiment

A power amplifier circuit 102 according to a second embodiment will be described. In the second embodiment and its subsequent embodiments, points common to the first embodiment will not be described, and only different points will be described. In particular, operational effects substantially the same due to substantially the same configurations will not be described in each embodiment.

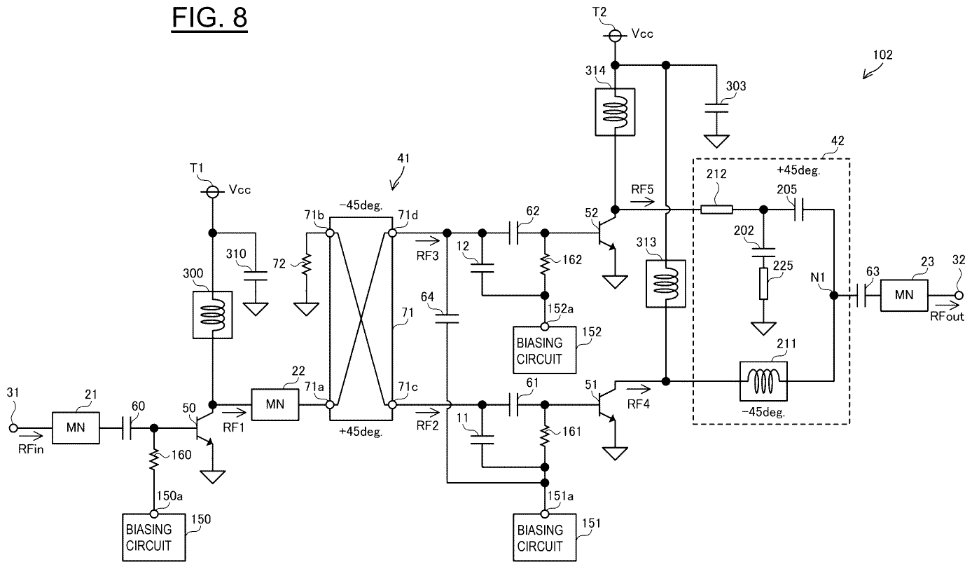

FIG. 8 is a circuit diagram of the power amplifier circuit 102. As illustrated in FIG. 8, the power amplifier circuit 102 is different from the power amplifier circuit 101 according to the first embodiment in that the capacitors 11 (fourth capacitor) and 12 (fifth capacitor) are further included.

The capacitor 11 has a first end connected to the port 71c of the 90° coupler 71, and a second end connected to the bias supply terminal 151a of the biasing circuit 151. Disposing the capacitor 11 causes a bypass path for high frequency components through the capacitors 11 and 61 to be formed across the resistive element 161.

The capacitor 12 has a first end connected to the port 71d of the 90° coupler 71, and a second end connected to the bias supply terminal 152a of the biasing circuit 152. Disposing the capacitor 12 causes a bypass path for high frequency components through the capacitors 12 and 62 to be formed across the resistive element 162.

In the power amplifier circuit 102, such a configuration further improves the AM/PM characteristics while substantially maintaining the PAE characteristics.

The exemplary embodiments of the present disclosure are described above. In the power amplifier circuits 101 and 102, the distributor circuit 41 distributes the amplified signal RF1 into the amplified signal RF2 and the amplified signal RF3 having a phase delayed from the phase of the amplified signal RF2, and has the ports 71c and 71d for outputting the amplified signals RF2 and RF3, respectively. The transistor device 51 has the base, which is connected to the port 71c through the capacitor 61 and which is supplied with the amplified signal RF2, and amplifies the amplified signal RF2 to output the amplified signal RF4. The transistor device 52 has the base, which is connected to the port 71d through the capacitor 62 and which is supplied with the amplified signal RF3, and amplifies the amplified signal RF3 to output the amplified signal RF5. The combining circuit 42 combines the amplified signal RF4 with the amplified signal RF5 to generate the output signal RFout. The biasing circuit 151 has the bias supply terminal 151a which supplies the first bias to the base of the transistor device 51 through the resistive element 161. The biasing circuit 152 has the bias supply terminal 152a which supplies the second bias to the base of the transistor device 52 through the resistive element 162. The capacitor 64 has the first end connected to the port 71d of the distributor circuit 41, and the second end connected to the bias supply terminal 151a of the biasing circuit 151.

Thus, the configuration, in which the capacitor 64 is disposed between the port 71d and the bias supply terminal 151a, may make the phase of the voltage at the bias supply terminal 151a close to the phase of the amplified signal RF2 at the port 71c. This improves the PAE of the power amplifier circuit 101 compared with that of the power amplifier circuit 901. In addition, the distortion characteristics may be improved. Therefore, a power amplifier that has the configuration including a distributor circuit adding a phase difference to an input signal for distribution, amplifier circuits amplifying the distributed signals, and a combining circuit combining the signals with reduction of the phase difference, and that enables the distortion characteristics and efficiency to be improved may be provided.

In the power amplifier circuit 102, the capacitor 11 has the first end connected to the port 71c of the distributor circuit 41, and the second end connected to the bias supply terminal 151a of the biasing circuit 151. The capacitor 12 has the first end connected to the port 71d of the distributor circuit 41, and the second end connected to the bias supply terminal 152a of the biasing circuit 152.

Such a configuration further improves the AM/PM characteristics while substantially maintaining the PAE characteristics.

The embodiments described above are described to facilitate understanding of the present disclosure, not for limited interpretation of the present disclosure. The present disclosure may be changed/improved without departing from the gist thereof, and encompasses equivalents thereof. That is, embodiments, which are obtained by those skilled in the art adding appropriate design change to each embodiment, are also encompassed in the scope of the present disclosure as long as having features of the present disclosure. For example, the components included in each embodiment, and their arrangement, materials, conditions, shapes, sizes, and so on are not limited to the illustrated ones, and may be changed appropriately. The embodiments are exemplary. Needless to say, partial replacement or combination of configurations illustrated in different embodiments may be made, and is encompassed in the scope of the present disclosure as long as having features of the present disclosure.
<1> A power amplifier circuit comprising: a distributor circuit that distributes a first signal into a second signal and a third signal having a phase delayed from the phase of the second signal, and that has a first output terminal and a second output terminal which output the second signal and the third signal, respectively; a carrier amplifier that has a first input terminal connected to the first output terminal through a first capacitor, the first input terminal being supplied with the second signal, and that amplifies the second signal to output a first amplified signal; a peak amplifier that has a second input terminal connected to the second output terminal through a second capacitor, the second input terminal being supplied with the third signal, and that amplifies the third signal to output a second amplified signal; a combining circuit that combines the first amplified signal with the second amplified signal to generate a third amplified signal; a first biasing circuit that has a first bias supply terminal which supplies a first bias to the first input terminal through a first resistive element; a second biasing circuit that has a second bias supply terminal which supplies a second bias to the second input terminal through a second resistive element; and a third capacitor that has a first end connected to the second output terminal and a second end connected to the first bias supply terminal.
<2> The power amplifier circuit according to <1>, further comprising: a fourth capacitor that has a first end connected to the first output terminal and a second end connected to the first bias supply terminal; and a fifth capacitor that has a first end connected to the second output terminal and a second end connected to the second bias supply terminal.

What is claimed is:

1. A power amplifier circuit comprising:
a distributor circuit configured to distribute a first signal into a second signal and a third signal having a phase delayed from the phase of the second signal, and that has a first output terminal and a second output terminal which output the second signal and the third signal, respectively;
a carrier amplifier that has a first input terminal connected to the first output terminal through a first capacitor, the first input terminal being supplied with the second signal, and the carrier amplifier being configured to amplify the second signal and to output a first amplified signal;
a peak amplifier that has a second input terminal connected to the second output terminal through a second capacitor, the second input terminal being supplied with the third signal, and the peak amplifier being configured to amplify the third signal and to output a second amplified signal;
a combining circuit configured to combine the first amplified signal with the second amplified signal, thereby generating a third amplified signal;
a first biasing circuit that has a first bias supply terminal which supplies a first bias to the first input terminal through a first resistive circuit element;
a second biasing circuit that has a second bias supply terminal which supplies a second bias to the second input terminal through a second resistive circuit element; and
a third capacitor that has a first end connected to the second output terminal and a second end connected to the first bias supply terminal.

2. The power amplifier circuit according to claim 1, further comprising:
a fourth capacitor that has a first end connected to the first output terminal and a second end connected to the first bias supply terminal; and
a fifth capacitor that has a first end connected to the second output terminal and a second end connected to the second bias supply terminal.
